(19) United States
(12) Patent Application Publication
(10) Pub. No.: US 2026/0130181 A1
(43) Pub. Date: May 7, 2026

(54) ISOLATED ACTIVE DEVICES AND METHODS FOR FORMING AND USING

(71) Applicant: Taiwan Semiconductor Manufacturing Company, LTD., Hsinchu (TW)

(72) Inventors: Kuan-Yu Chen, Taoyuan (TW); Yu-Hsing Chang, Taipei (TW); Ching-Hsiang Hsieh, Taoyuan (TW); Chung-Chuan Tseng, Hsinchu (TW)

(21) Appl. No.: 18/934,369

(22) Filed: Nov. 1, 2024

(51) Int. Cl. H01L 21/762; H01L 27/12

(52) U.S. Cl. CPC H10P 90/1906; H10P 90/1916; H10W 10/014; H10W 10/061; H10W 10/17; H10W 10/181; H10D 86/201

(57) ABSTRACT

Methods for forming a silicon-on-insulator (SOI) substrate are disclosed. A substrate includes a sacrificial layer and a first substrate layer over the sacrificial layer. Vias are formed around a first substrate region of the first substrate layer down to the sacrificial layer. The sacrificial layer is etched away, forming a buried volume. Substrate supports connecting the first substrate region to the first substrate layer are converted into a dielectric material. The buried volume and the vias are filled with a first dielectric material, forming a buried dielectric layer and a first dielectric sidewall around the first substrate region. A second substrate layer is formed over the first substrate layer. A trench is formed around a second substrate region of the second substrate layer. The trench is filled with a second dielectric material to form a second dielectric sidewall around the second substrate region connected to the first dielectric sidewall.

### BACKGROUND

Integrated circuits are formed on a semiconductor wafer. Photolithographic patterning processes use ultraviolet light to transfer a desired mask pattern to a photoresist on a semiconductor wafer. Etching processes may then be used to transfer to the pattern to a layer below the photoresist. This process is repeated multiple times with different patterns to build different conductive, resistive, and/or insulating layers on the wafer substrate and make a useful semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a perspective view of a silicon-on-insulator (SOI) substrate, in accordance with some embodiments of the present disclosure. FIG. 1B is a plan view of FIG. 1A. FIG. 1C is a Y-axis cross-sectional view through line C-C of FIG. 1B. FIG. 1D is a Y-axis cross-sectional view through line D-D of FIG. 1B. FIG. 1E is an X-axis cross-sectional view through line E-E of FIG. 1B. FIG. 1F is an X-axis cross-sectional view through line F-F of FIG. 1B.

FIG. 2 is a flow chart illustrating a method for making an SOI substrate, in accordance with some embodiments.

FIG. 3A is a perspective view of a substrate with a sacrificial layer formed therein. FIG. 3B is a Y-axis cross-sectional view through line B-B of FIG. 3A.

FIG. 4A is a perspective view of the substrate either after deposition of a substrate layer to bury the sacrificial layer, or in an alternative embodiment after ion implantation within the substrate to form the sacrificial layer. FIG. 4B is a Y-axis cross-sectional view through line B-B of FIG. 4A.

FIG. 5A is a perspective view of the substrate after etching of vias through the silicon layer down to the sacrificial layer and subsequent lateral etching to remove the sacrificial layer. FIG. 5B is a Y-axis cross-sectional view through line B-B of FIG. 5A. FIG. 5C is a Y-axis cross-sectional view through line C-C of FIG. 5A.

FIG. 6A is a perspective view of the substrate after oxidation of substrate supports. FIG. 6B is a Y-axis cross-sectional view through line B-B of FIG. 6A. FIG. 6C is a Y-axis cross-sectional view through line C-C of FIG. 6A.

FIG. 7A is a perspective view of the substrate after formation of a buried dielectric layer in the etched areas. A first dielectric sidewall is also formed around a first substrate region. FIG. 7B is a Y-axis cross-sectional view through line B-B of FIG. 7A. FIG. 7C is a Y-axis cross-sectional view through line C-C of FIG. 7A.

FIG. 8A is a perspective view of the substrate after deposition of another substrate layer over the first substrate layer. FIG. 8B is a Y-axis cross-sectional view through line B-B of FIG. 8A. FIG. 8C is a Y-axis cross-sectional view through line C-C of FIG. 8A.

FIG. 9A is a perspective view of the substrate after etching to form a trench that exposes the first dielectric sidewall. The trench surrounds a second substrate region. FIG. 9B is a Y-axis cross-sectional view through line B-B of FIG. 9A. FIG. 9C is a Y-axis cross-sectional view through line C-C of FIG. 9A.

FIG. 10A is a perspective view of the substrate after deposition of dielectric material into the trench to form a second dielectric sidewall and obtain the SOI substrate. FIG. 10B is a plan view of FIG. 1A. FIG. 10C is a Y-axis cross-sectional view through line C-C of FIG. 10A. FIG. 10D is a Y-axis cross-sectional view through line D-D of FIG. 10A.

FIGS. 11A-11C are Y-axis cross-sectional views of different embodiments of the SOI substrate. In these figures, the thickness of the first substrate region may vary.

FIGS. 12A-12C are Y-axis cross-sectional views of different embodiments of the SOI substrate. In these figures, the thickness of the second substrate region may vary.

FIGS. 13A-13C are Y-axis cross-sectional views of different embodiments of the SOI substrate. In these figures, the ratio of the thickness of the second substrate region to the thickness of the first substrate region may vary.

FIGS. 14A-14C are Y-axis cross-sectional views of different embodiments of the SOI substrate. In these figures, the horizontal dimensions (i.e. length and width, or Y-axis and X-axis) of the trench may vary. In addition, different vertically-oriented layers may be present within the trench.

FIGS. 15A-15D are Y-axis cross-sectional views of different embodiments of the SOI substrate. In these figures, the location of the trench may be shifted along the Y-axis and/or X-axis. Again, different vertically-oriented layers may be present within the trench.

FIGS. 16A-16D are Y-axis cross-sectional views of different embodiments of the SOI substrate. In these figures, the depth of the trench may vary. This may change the shape of the first substrate region and/or the second substrate region.

FIG. 17 is a Y-axis cross-sectional view showing examples of different semiconductor devices which can be formed upon the SOI substrate.

FIG. 18 is a flow chart illustrating a method for making a semiconductor device, especially on an SOI substrate, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The figures may provide views of the substrate across three different axes. The “Y-axis cross-sectional view” is arbitrarily designated as corresponding to the length, such that the length and depth/height of the substrate are shown, with the width extending into the page. The “X-axis cross-sectional view” is arbitrarily designated as corresponding to the width, such that the width and depth/height of the substrate are shown, with the length extending into the page. These terms should not be construed as implying the length must have a greater value than the width.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure relates to structures which are made up of different layers. When the terms “on” or “upon” or “over” are used with reference to two different layers (including the substrate), they indicate merely that one layer is on or upon or over the other layer. These terms do not require the two layers to directly contact each other, and permit other layers to be between the two layers. For example all layers of the structure can be considered to be “on” or “over” the substrate, even though they do not all directly contact the substrate. The term “directly” may be used to indicate two layers directly contact each other without any layers in between them. In addition, when referring to performing process steps upon the substrate or over the substrate, this should be construed as performing such steps to whatever layers may be present on the substrate as well, depending on the context.

The present disclosure relates to silicon-on-insulator (SOI) substrates and methods for making and using such SOI substrates. The substrate is a layered semiconductor-insulator-semiconductor substrate, such as silicon-silicon dioxide-silicon substrate, rather than a bulk semiconductor substrate. Semiconductor devices constructed on the upper silicon layer are electrically isolated from the bulk silicon, which lowers parasitic capacitance, which improves power consumption. In addition, crosstalk arising from capacitive, inductive, and/or conductive coupling between separate devices on the same substrate can be reduced. In the present disclosure, SOI substrates are disclosed which include an insulator structure below the upper silicon layer and around all sides of the upper silicon layer. This may be useful in high-voltage devices (operating 5 volts or higher) for withstanding high voltages and obtaining full directional isolation performance. Such substrates can also be produced in-house at a foundry and adapted for specific device needs.

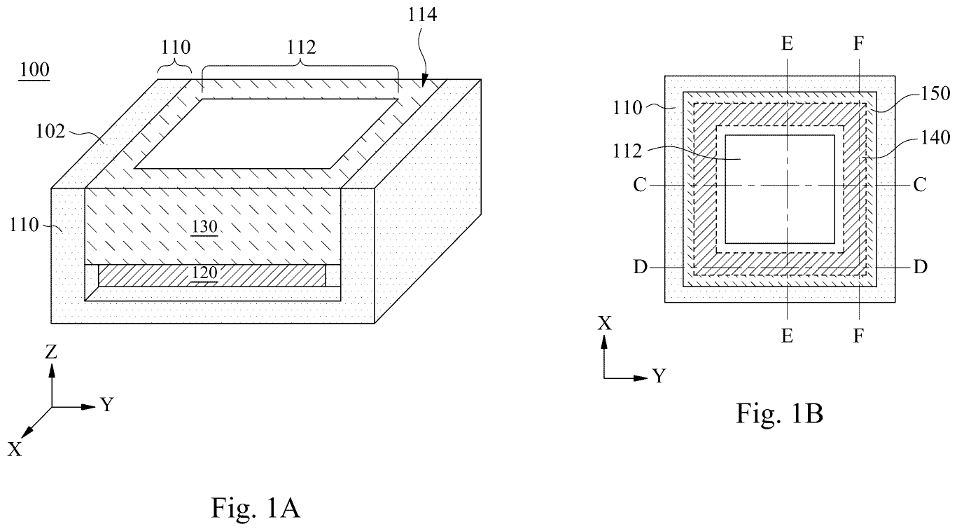

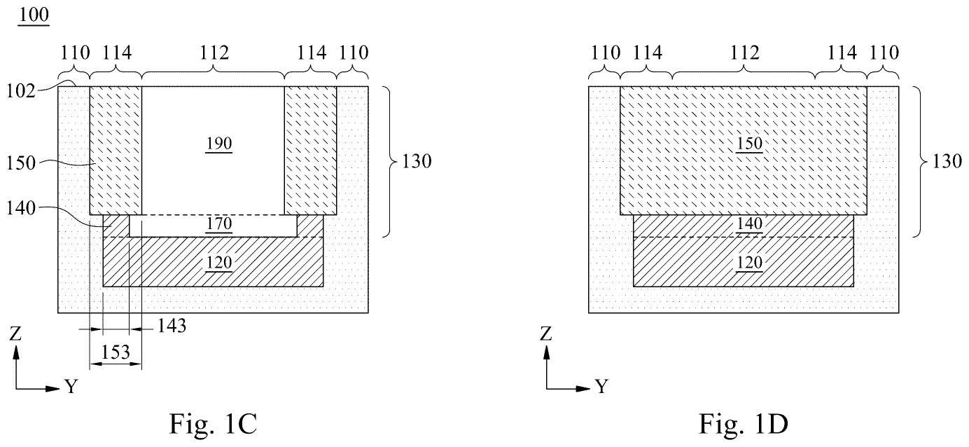

FIGS. 1A-1E are various views of a silicon-on-insulator (SOI) substrate 100 of the present disclosure. FIG. 1A is a perspective view. FIG. 1B is a plan view. FIG. 1C is a Y-axis cross-sectional view through line C-C of FIG. 1B. FIG. 1D is a Y-axis cross-sectional view through line D-D. FIG. 1E is an X-axis cross-sectional view through line E-E. FIG. 1F is an X-axis cross-sectional view through line F-F.

Referring first to FIG. 1A and FIG. 1C, the substrate 100 includes a bulk region 110 which is separated from an active region 112 by a dielectric structure 114. The active region 112 is located within the dielectric structure 114. As illustrated here, the dielectric structure 114 resembles five sides of a cube. The dielectric structure includes a buried dielectric layer 120 in the X-Y plane and a vertical dielectric sidewall 130 forming four sides that extend upwards in the Z-axis from the buried dielectric layer to the upper surface 102 of the substrate. As illustrated here, the vertical dielectric sidewall may be considered as including a first dielectric sidewall 140 and a second dielectric sidewall 150. The first dielectric sidewall 140 contacts the buried dielectric layer 120, and is below the second dielectric sidewall 150. The second dielectric sidewall 150 extends from the first dielectric sidewall 140 to the upper surface 102 of the substrate. In FIG. 1C, the thickness 143 of the first dielectric sidewall is different from the thickness 153 of the second dielectric sidewall. In the plan view of FIG. 1B, the location of the first dielectric sidewall 140 is indicated with dashed lines.

Continuing, in FIG. 1C, the active region 112 may be divided into a first substrate region 170 which is located below a second substrate region 190. The first dielectric sidewall 140 surrounds the first substrate region 170, and the second dielectric sidewall 150 surrounds the second substrate region 190. As best seen in both FIG. 1D and FIG. 1F, the vertical dielectric sidewall 130 completely isolates the active region 112 from the bulk region 110 of the substrate.

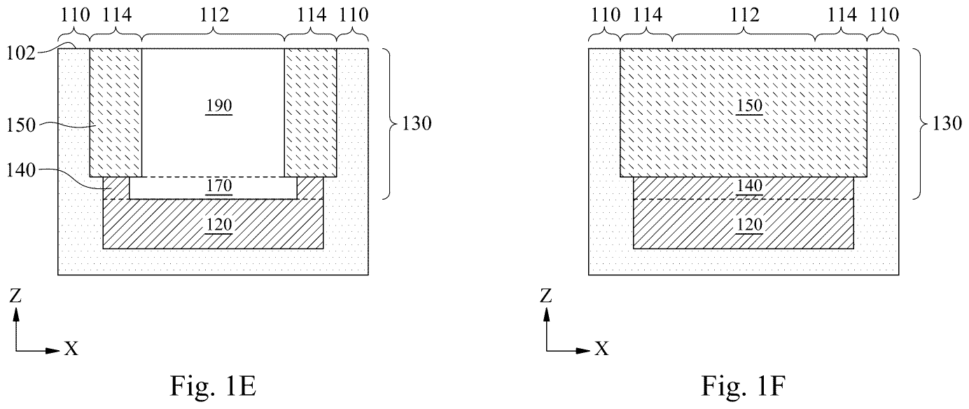

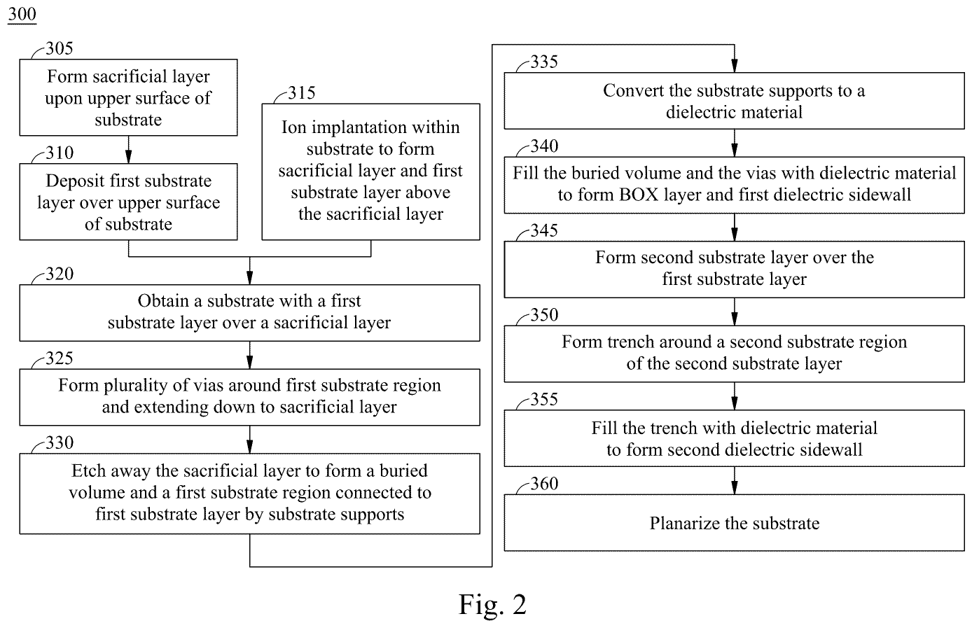

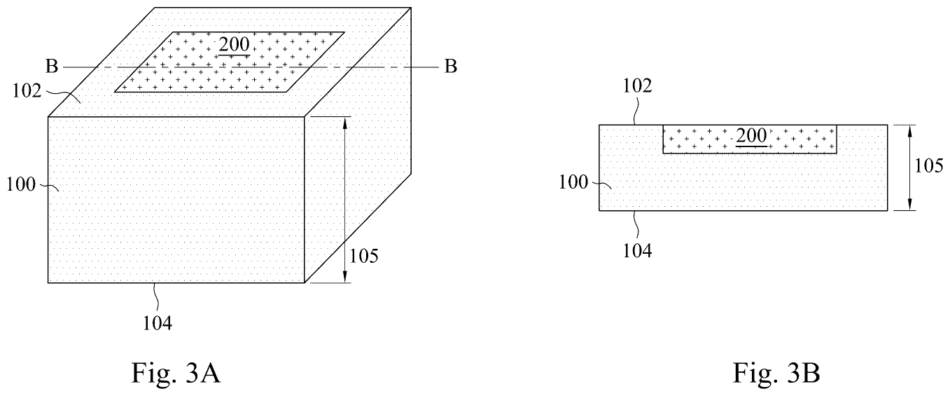

FIG. 2 is a flow chart illustrating a method 300 for forming an SOI substrate, in accordance with some embodiments. Some steps of the method are also illustrated in FIGS. 3A-10C. These figures provide different views for better understanding. It is noted that in these figures, only Y-axis cross-sectional views are illustrated, and for these example figures, it may be assumed that the X-axis cross-sectional views are similar to the Y-axis views. While the method steps are discussed below in terms of forming a single active region, such discussion should also be broadly construed as applying to the concurrent formation of multiple active regions on a substrate. Other structures may also be concurrently formed. It is noted that not all steps described in the flow chart are required.

Referring first to FIG. 3A and FIG. 3B, the method begins with a substrate 100. The substrate may be, for example, a wafer made of a semiconducting material. Such semiconductor materials can include silicon, for example in the form of crystalline Si. In alternative embodiments, the substrate can be made of other elementary semiconductors such as germanium, silicon carbide (SiC), silicon germanium, or silicon germanium carbide. The substrate may alternatively include a compound semiconductor such as gallium arsenide (GaAs), gallium phosphide, gallium carbide, indium arsenide (InAs), indium phosphide (InP), gallium arsenic phosphide, gallium indium phosphide, cadmium telluride, or cadmium sulfide. In particular embodiments, the substrate is silicon. The substrate 100 has an upper surface 102 and a lower surface 104, and has a thickness 105 between these two surfaces.

Next, as indicated in step 320 of FIG. 2, a sacrificial layer 200 is formed within the substrate 100, with a first substrate layer 160 being present over the sacrificial layer 200. At least two different ways of obtaining such a structure are contemplated.

In one method, as indicated in step 305 of FIG. 2 and as illustrated in FIG. 3A and FIG. 3B, the sacrificial layer 200 is formed upon the upper surface 102 of the substrate. This is typically performed by doping the substrate with a dopant of the opposite charge. For example, if the substrate is a p-substrate, then the sacrificial layer would be formed by doping with an n-type dopant, and vice versa.

The doping may be performed by ion implantation or other suitable methods. Briefly, in ion implantation, an ion implanter is used to implant atoms into a silicon crystal lattice, modifying the conductivity of the lattice in the implanted location. An ion implanter generally includes an ion source, a beam line, and a process chamber. The ion source produces the desired ions. The beam line organizes the ions into a beam having high purity in terms of ion mass, energy, and species. A mask, such as a patterned photoresist layer or a hard mask layer, is used to expose desired regions of the substrate. The ion beam is then used to irradiate the semiconducting wafer substrate in a process chamber. The ion beam strikes the exposed regions on the wafer substrate, and the ions can be implanted into the substrate as dopants at desired depths. Alternatively, the substrate can be partially etched, followed by blanket deposition of the dopant, following by annealing in which the dopant reacts with the underlying exposed silicon.

Common n-type dopants for silicon substrates may include nitrogen (N), phosphorus (P), arsenic (As), bismuth (Bi), or tantalum (Ta). Common p-type dopants for silicon substrates may include boron (B), aluminum (Al), gallium (Ga), or indium (In).

In some embodiments, the dopant is implanted at a concentration of about 1×10¹⁹ cm⁻² or greater, such as from about 1×10¹⁹ to about 1×10²¹ cm⁻². In particular embodiments, the dopant may be implanted at an energy of about 5 keV to about 20 keV to form the sacrificial layer upon the surface. Other ranges for each of these settings fall within the scope of this disclosure. Any suitable implant angle may be used.

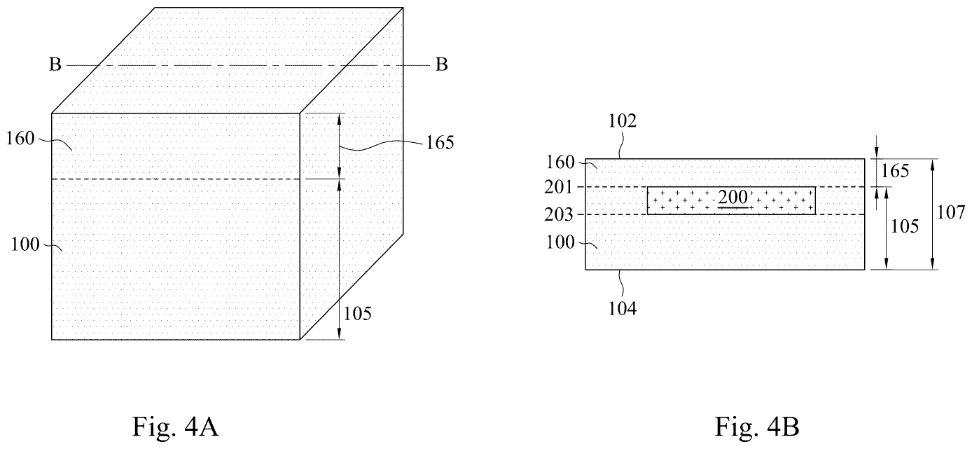

Then, as indicated in step 310 of FIG. 2 and as illustrated in FIG. 4A and FIG. 4B, a first substrate layer 160 is deposited over the upper surface of the substrate. This may be done, for example, by chemical vapor deposition (CVD), physical vapor deposition (PVD), or other suitable methods. It is noted that the first substrate layer 160 will have the same lattice quality as that of the substrate. The first substrate layer has a height or depth 165, and the first substrate layer 160 may also now be considered to be part of the substrate 100. This two-step process is the first way to obtain the structure of step 320. If desired, the upper surface 102 of the substrate/first substrate layer may be planarized to obtain a level surface. This may be done, for example, by chemical mechanical polishing (CMP), where the surface of a wafer is leveled using relative motion between the wafer and a rotating polishing pad to which a slurry is applied. Downward pressure is applied to push the wafer against the polishing pad, and elevated elements are worn down to obtain a surface with low surface roughness.

The second way to obtain the structure of step 320, again illustrated in FIG. 4A and FIG. 4B, begins with a substrate 100 having height 107 which is equal to the sum of the two heights 105 and 165. In step 315 of FIG. 2, ion implantation is performed to form the sacrificial layer 200 within the substrate 100. In FIG. 4B, the sacrificial layer is formed between depths 201, 203. The first substrate layer 160 is then defined as the portion of the substrate that is located above the sacrificial layer 200.

In particular embodiments, the dopant may be implanted at a concentration of about 1×10¹⁹ cm⁻² or greater, such as from about 1×10¹⁹ to about 1×10²¹ cm⁻². In particular embodiments, the dopant may be implanted at an energy of about 20 keV to about 2500 keV, depending on the thickness of the substrate and the desired depth for the sacrificial layer. Other ranges for each of these settings fall within the scope of this disclosure. Any suitable implant angle may be used.

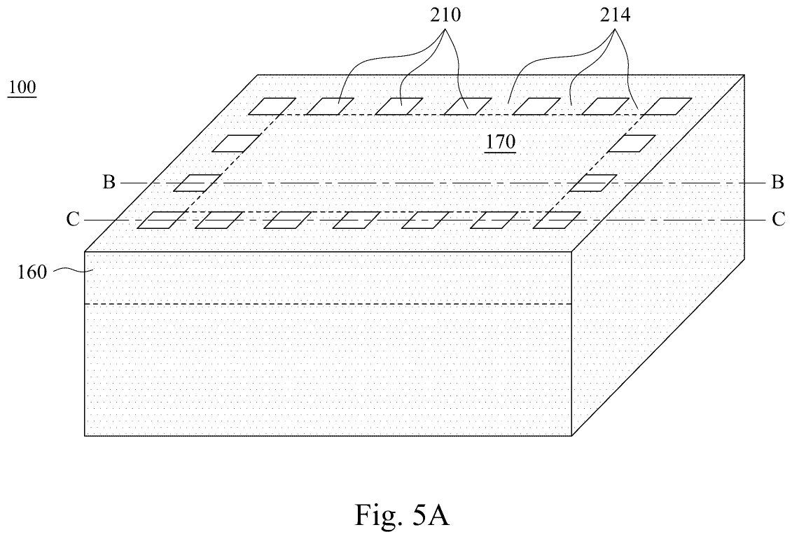

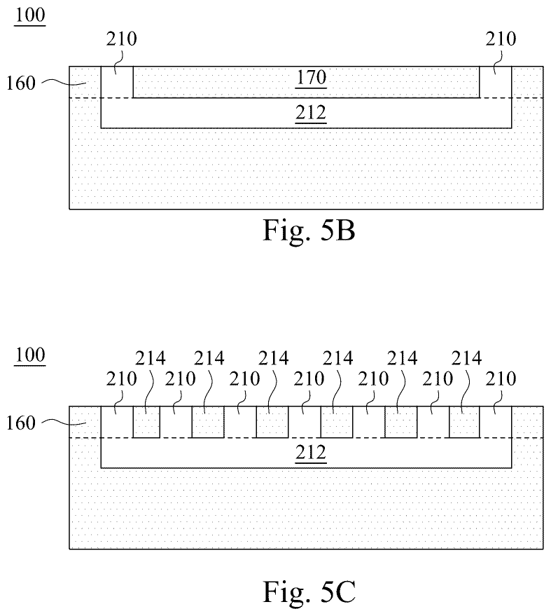

Continuing, then, after the sacrificial layer has been formed underneath the first substrate layer, as indicated in step 325 of FIG. 2 and as best illustrated in FIG. 5A, a plurality of vias 210 is formed around a first substrate region 170 of the first substrate layer 160. As best seen in FIG. 5B and FIG. 5C, the vias extend down to the sacrificial layer 200. This may be performed by appropriate patterning of a mask, etching, and removal of the mask. Then, in step 330 of FIG. 2, the sacrificial layer is etched away to form a buried volume 212. The sacrificial layer permits high etch selectivity. This may be done using a dry etch process. In particular, the lateral etching may be performed using a selective gas etchant.

The first substrate region 170 is supported above the buried volume by a plurality of substrate supports 214, which join the first substrate region 170 to the first substrate layer 160. It is noted that although the vias 210 and the substrate supports 214 are illustrated here as having a rectangular shape, they may have any shape. For example, the vias may be circular.

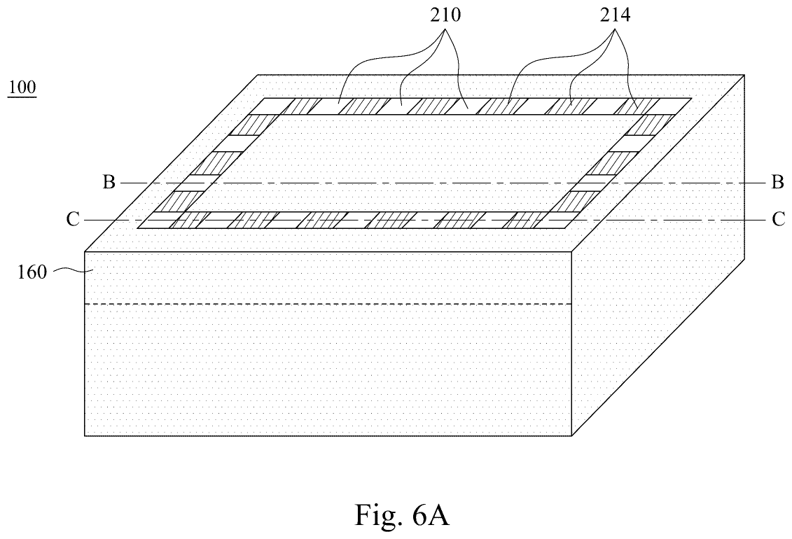

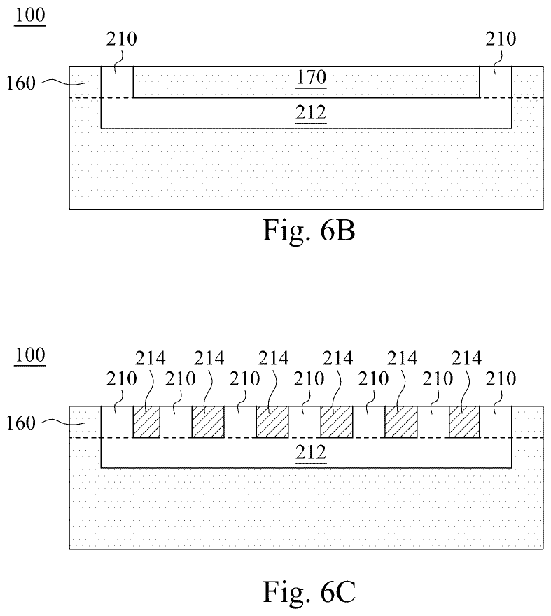

Next, as indicated in step 335 of FIG. 2 and as illustrated in FIGS. 6A-6C, the plurality of substrate supports 214 are converted into a dielectric material. For example, the substrate supports may originally have been silicon, and can be converted to a dielectric material by thermal oxidation. This may be done, for example, by first applying a mask (such as a nitride hard mask) to the first substrate layer 160 and patterning the mask to expose only the substrate supports. Thermal oxidation may then be performed to convert the silicon of the substrate supports to silicon dioxide, which is a dielectric material. Although not illustrated here, it is possible that the exposed surfaces of the buried volume and the lower surface of the first substrate region may also be converted to the dielectric material. The mask is then removed.

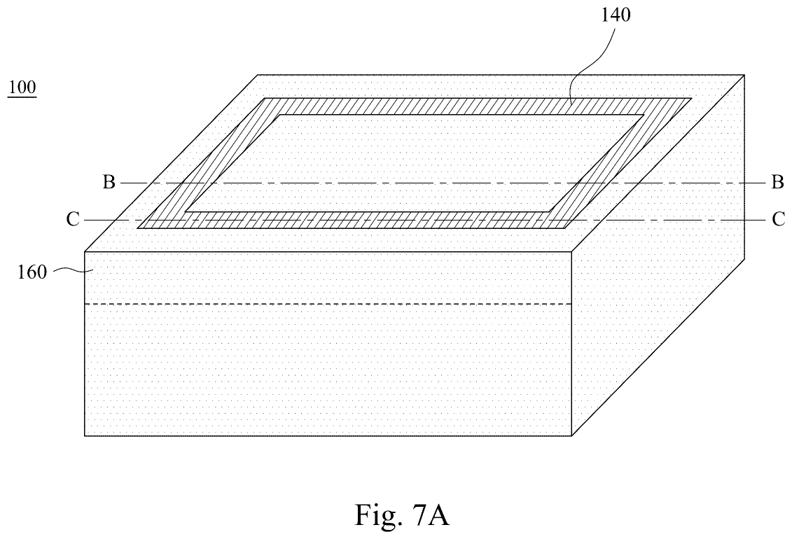

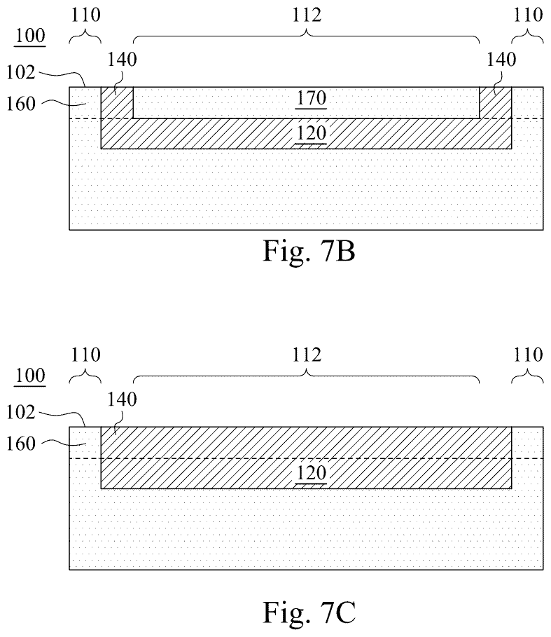

Next, as indicated in step 340 of FIG. 2 and as illustrated in FIGS. 7A-7C, the buried volume and the plurality of vias are filled with a first dielectric material to form a buried dielectric layer 120 and a first dielectric sidewall 140 around the first substrate region 170. As illustrated here, the first dielectric material is the same dielectric material that the substrate supports were converted to, however this is not required.

The buried dielectric layer may be made of any suitable electrically insulating material. For example, in particular embodiments, the buried dielectric layer is formed from an oxide, such as silicon dioxide, and may be known as a buried oxide layer or BOX layer. However, the buried dielectric layer could also be formed from a nitride, such as silicon nitride.

Any suitable deposition process may be used. For example, using CVD, a silicon-containing source gas may act as a silicon precursor that reacts with an oxygen-containing source gas. Examples of such silicon precursors include but are not limited to tetraethyl orthosilicate (TEOS), trimethylsilane, tetramethylsilane, and hexachlorodisilane (HCDS). Ozone (O₃) can be used to provide oxygen atoms for the reaction. At temperatures of about 300° C. to about 500° C. or higher, these gases will react to deposit silicon dioxide. The precursors can be blown in underneath the first substrate region to fill the buried volume.

As indicated in FIG. 7B, the first dielectric sidewall 140 extends from the buried dielectric layer 120 to the upper surface 102 of the substrate/first substrate layer. As best seen in FIG. 7C, the first dielectric sidewall 140 is desirably solid and desirably does not contain any holes. Thus, the active region 112 within the first dielectric sidewall is electrically isolated from the bulk region 110 outside the first dielectric sidewall. Planarization may be performed if desired.

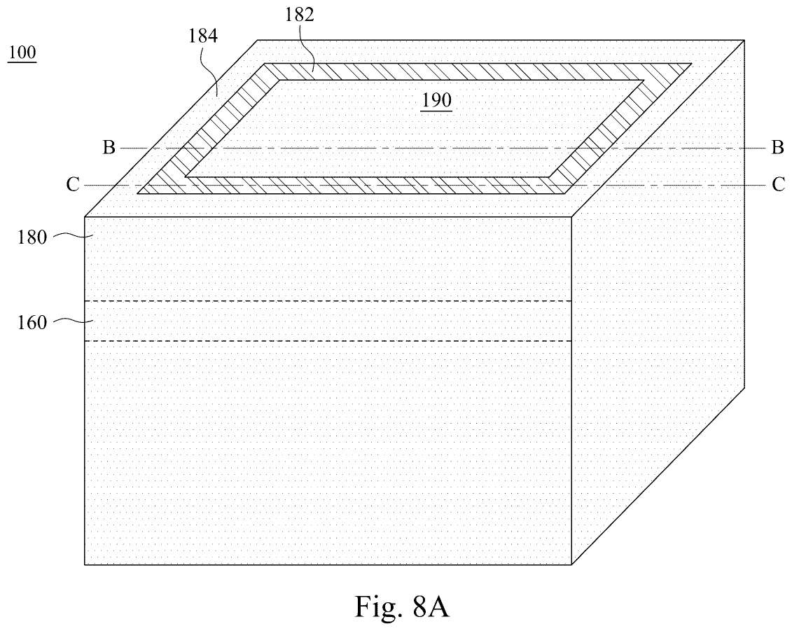

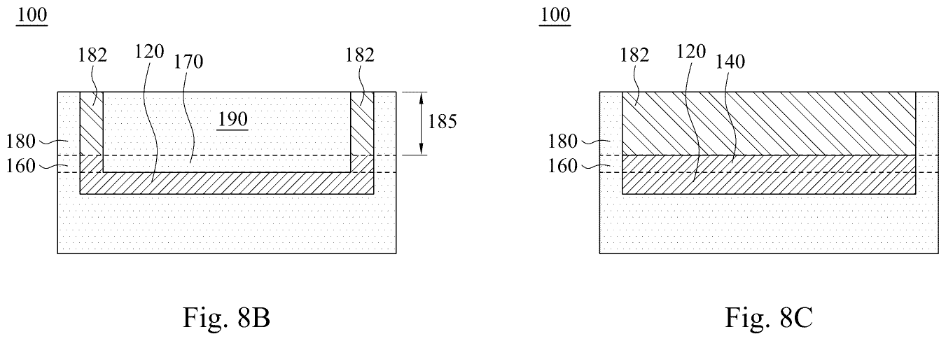

Continuing, as indicated in step 345 of FIG. 2 and as illustrated in FIGS. 8A-8C, a second substrate layer 180 is formed over the substrate/first substrate layer 160. This may be done by CVD, PVD, or other suitable methods. The second substrate layer has a height or depth 185, and may also be considered to be part of the substrate 100. Planarization may be performed if desired.

It is noted that the second substrate layer 180 will not have a uniform lattice quality. Here, the second substrate layer 180 may be considered to include a second substrate region 190 which is located over the first substrate region 170. The second substrate layer also includes a sidewall region 182 surrounding the second substrate region, and located over the first dielectric sidewall 140. Finally, the second substrate layer also includes a bulk region 184 located outside the sidewall region. The second substrate region 190 will have a lattice quality like that of the first substrate region 170, and the bulk region 184 will have a lattice quality like that of the substrate/first substrate layer 160. The lattice quality of the sidewall region 182, however, will differ from the lattice quality of the second substrate region 190 because it is formed or grown upon the first dielectric sidewall 140.

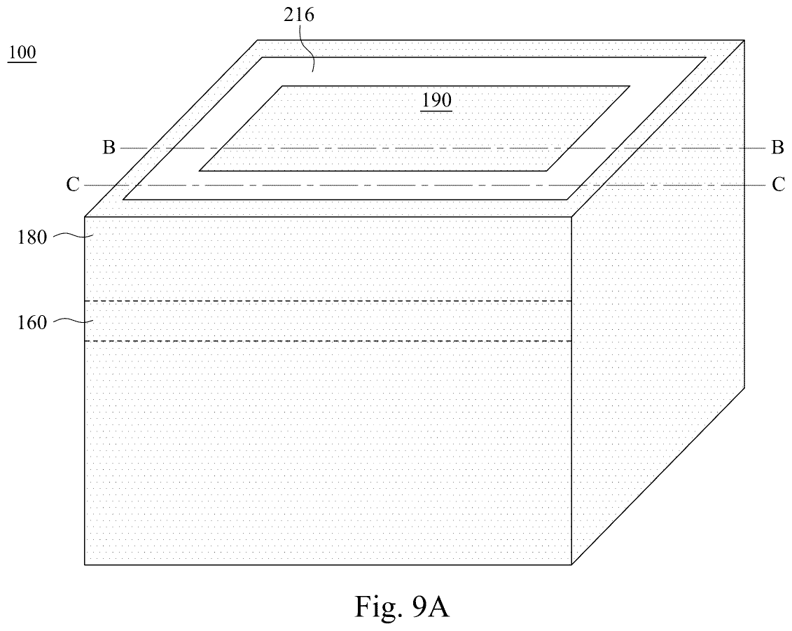

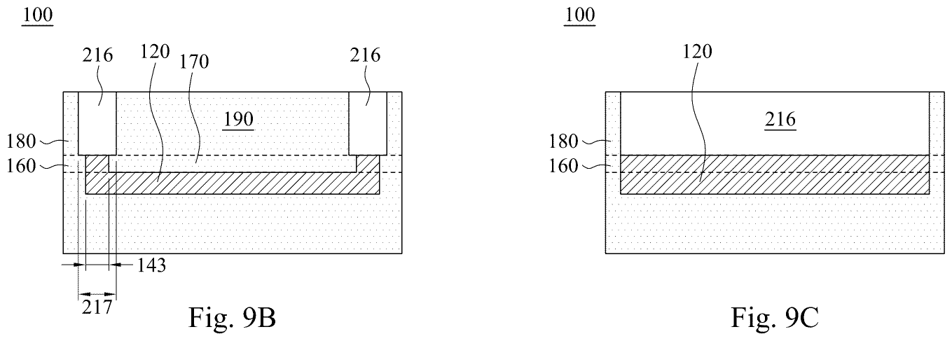

Then, as indicated in step 350 of FIG. 2 and as illustrated in FIGS. 9A-9C, a trench 216 is formed around the second substrate region 190 of the second substrate layer 180. The trench is formed over the first dielectric sidewall 140, and as illustrated removes the sidewall region 182 which had a different lattice quality compared to the second substrate region 190. As best seen in FIG. 9B, in some particular embodiments, the trench 216 has a thickness 217 which is greater than the thickness 143 of the first dielectric sidewall. However, this is not required. The trench may be formed, for example, by patterning of a mask, then performing a dry etching or other etching process, then removing the mask.

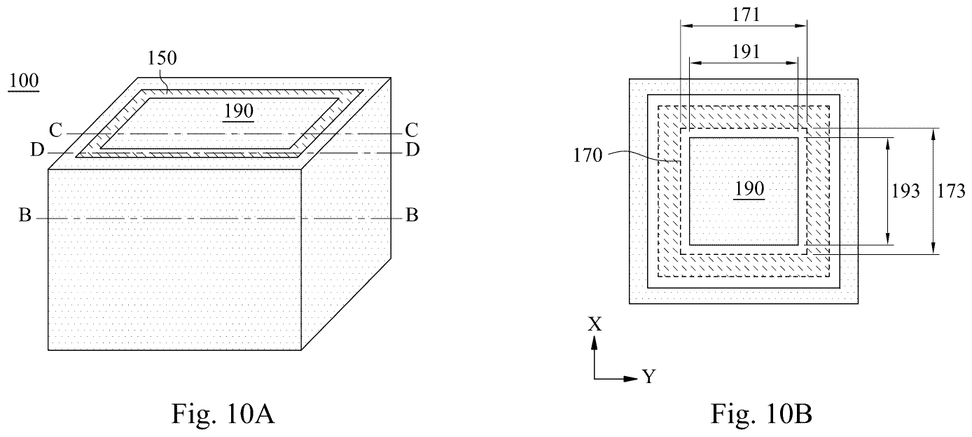

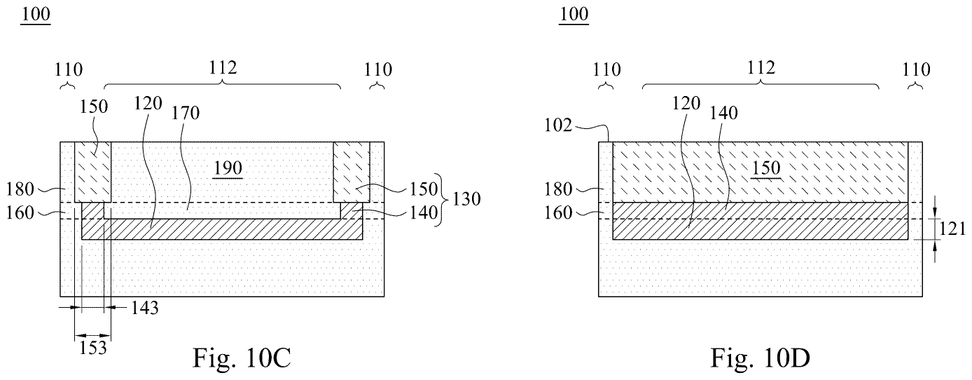

Next, as indicated in step 355 of FIG. 2 and as illustrated in FIGS. 10A-10D, the trench 216 is filled with a second dielectric material to form a second dielectric sidewall 150 around the second substrate region 190. The combination of the second dielectric sidewall 150 and the first dielectric sidewall 140 forms the vertical dielectric sidewall 130. It is noted that the first dielectric material and the second dielectric material may be the same material, or may be different materials. In particular embodiments, they are both silicon dioxide. Planarization may be performed if desired.

As indicated in FIG. 10C, the second dielectric sidewall 150 contacts the first dielectric sidewall 140 and extends upwards to the upper surface 102 of the substrate/second substrate layer. In some particular embodiments, the thickness 153 of the second dielectric sidewall is greater than the thickness 143 of the first dielectric sidewall. However, this is not required. The second dielectric sidewall 150 overlaps the first dielectric sidewall 140. A dashed line indicates the boundary between the first substrate region 170 and the second substrate region 190. It is noted that in an actual SOI substrate, the first substrate region 170 and the second substrate region 190 are made of the same material and may not be visually distinguishable from each other.

As best seen in FIG. 10D, the second dielectric sidewall 150 is desirably solid and desirably does not contain any holes. Thus, in combination with the buried dielectric layer 120, the active region 112 within the vertical dielectric sidewall is electrically isolated from the bulk region 110 outside the vertical dielectric sidewall.

In step 360 of FIG. 2, the upper surface 102 of the SOI substrate may be planarized to obtain a level surface. This may be done, for example, by CMP. The resulting SOI substrate 100 is illustrated in FIGS. 10A-10D.

Referring to the plan view of FIG. 10B, the length 171 and width 173 of the first substrate region 170 are indicated, along with the length 191 and width 193 of the second substrate region 190. In particular embodiments, these lengths and widths 171, 173, 191, 193 may independently vary from about 0.1 micrometers (μm) to about 1000 μm. In some additional embodiments, the length 171 and width 173 of the first substrate region 170 are equal to each other (i.e. the first substrate region is a square). In other additional embodiments, the length 191 and width 193 of the second substrate region 190 are equal to each other (i.e. the second substrate region is a square). In still additional embodiments, the length 171 and width 173 of the first substrate region 170 are both greater than the length 191 and width 193 of the second substrate region 190. In particular embodiments, then, the surface area of the second substrate region is different from the surface area of the first substrate region. The surface area is visible in the plan view, and is the product of the length and width. In some embodiments, the surface area of the second substrate region is greater than the surface area of the first substrate region. In some embodiments, the surface area of the second substrate region is less than the surface area of the first substrate region. Referring to FIG. 10D, in particular embodiments, the thickness 121 of the buried dielectric layer 120 may range from about 0.1 μm to about 10 μm. Other ranges and values for each of these measurements are also within the scope of the disclosure.

The depth/heights 175, 195 of the first substrate region 170 and the second substrate region 190 may vary as desired. This is illustrated in FIGS. 11A-11C. The depth would be considered relative to the upper surface 102 of the SOI substrate, whereas the height would be considered relative to the upper surface 122 of the buried dielectric layer 120. In FIG. 11A, the depth 175 of the first substrate region is less than the depth 195 of the second substrate region. In FIG. 11B, the depth 175 of the first substrate region about the same as the depth 195 of the second substrate region. In FIG. 11C, the depth 175 of the first substrate region is greater than the depth 195 of the second substrate region. The relative depths 145, 155 of the first dielectric sidewall 140 and the second dielectric sidewall 150 also change in the same manner. In particular embodiments, the depth/heights 175, 195 of the first substrate region 170 and the second substrate region 190 are independently from about 0.1 micrometers (μm) to about 10 micrometers. However, other ranges and values are within the scope of the present disclosure.

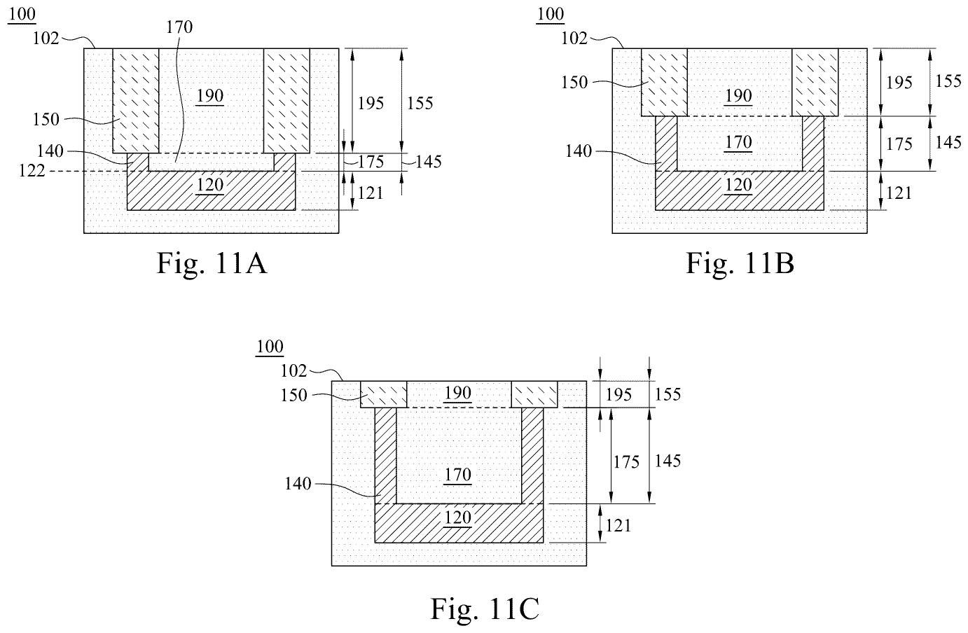

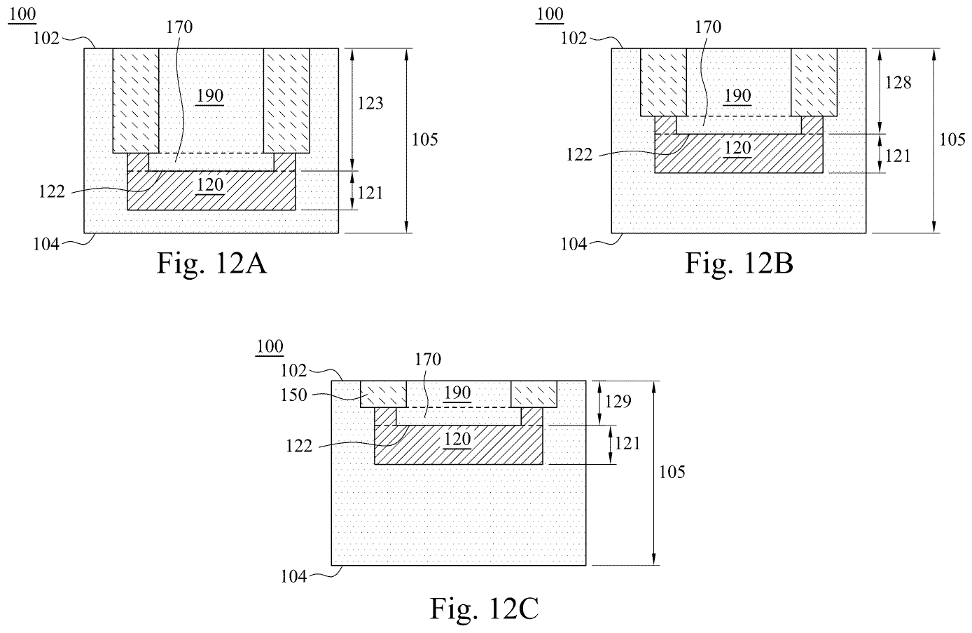

The depth/heights of the buried dielectric layer 120 within the SOI substrate 100 may also vary as desired. This is illustrated in FIGS. 12A-12C. In each of these figures, the SOI substrate 100 has a thickness 105 between the upper surface 102 and the lower surface 104. The SOI substrate thickness 105 is the same in all three figures. The buried dielectric layer thickness 121 is also the same in all three figures. The depth/height 123 of the upper surface 122 of the buried dielectric layer in FIG. 12A is greater than the depth/height 128 of the upper surface 122 of the buried dielectric layer in FIG. 12B. The depth/height 128 of the upper surface 122 of the buried dielectric layer in FIG. 12B is greater than the depth/height 129 of the upper surface 122 of the buried dielectric layer in FIG. 12C. The SOI substrate thickness 105 itself may also be varied as desired.

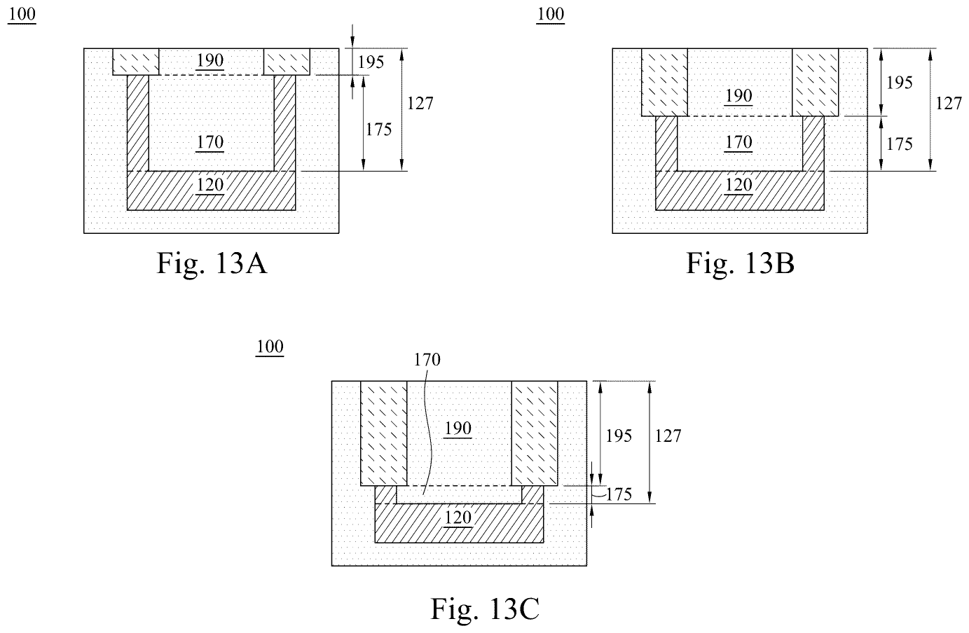

The ratio of the depth/height 195 of the second substrate region 190 to the depth/height 175 of the first substrate region 170 may vary as desired. This is illustrated in FIGS. 13A-13C. The depth 127 of the buried dielectric layer 120 is the same in all three figures. In FIG. 13A, the depth 195 of the second substrate region is less than the depth 175 of the first substrate region. Thus, their ratio is less than 1. In FIG. 13B, the depth 195 of the second substrate region is about the same as the depth 175 of the first substrate region. Thus, their ratio is close to 1. In FIG. 13C, the depth 195 of the second substrate region is greater than the depth 175 of the first substrate region. Thus, their ratio is greater than 1. In particular embodiments, the ratio of the depth 195 of the second substrate region 190 to the depth 175 of the first substrate region 170 is from about 0.1 to about 100. However, other ranges and values are within the scope of the present disclosure.

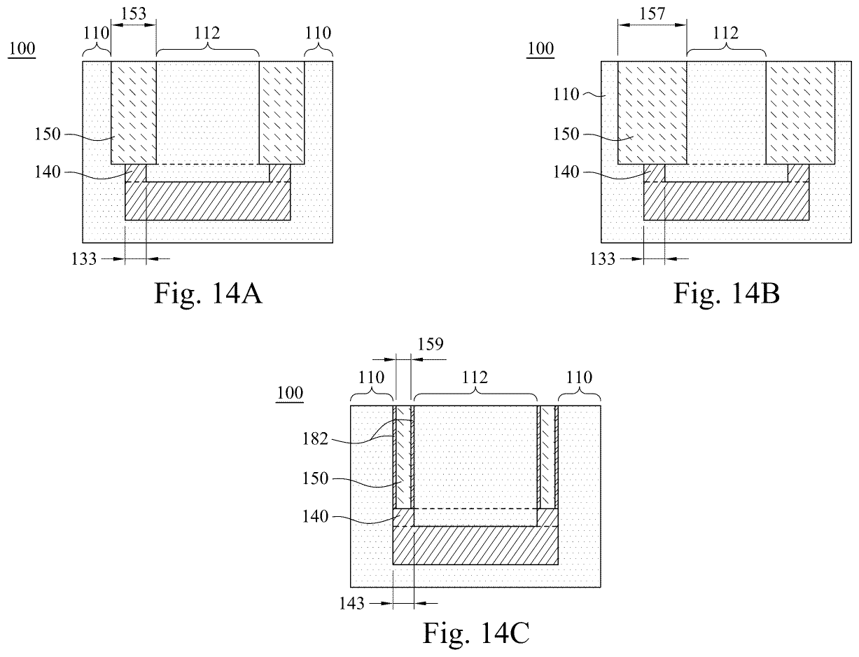

The thickness of the second dielectric sidewall 150 may vary as desired. This is illustrated in FIGS. 14A-14C. The thickness 153 in FIG. 14A is less than the thickness 157 in FIG. 14B. In both FIG. 14A and FIG. 14B, the thickness 153, 157 of the second dielectric sidewall 150 is greater than the thickness 143 of the first dielectric sidewall 140. Similarly, the thickness 159 in FIG. 14C is less than the thickness 153 in FIG. 14A. In FIG. 14C, portions of the sidewall region 182 (see FIG. 8B) are still present around the second dielectric sidewall 150. Here, the thickness 159 of the second dielectric sidewall 150 is less than the thickness 143 of the first dielectric sidewall 140. The first dielectric sidewall 140 and the second dielectric sidewall 150 always overlap. This maintains electrical isolation between the active region 112 and the bulk region 110.

In particular embodiments, the thicknesses 153, 143 of the second dielectric sidewall 150 and the first dielectric sidewall 140 are independently from about 0.1 micrometers (μm) to about 10 micrometers. However, other ranges and values are within the scope of the present disclosure.

As noted in FIG. 14A and FIG. 14B, in particular embodiments, the overlap 133 between the first dielectric sidewall 140 and the second dielectric sidewall 150 is at least 0.040 micrometers (i.e. 40 nanometers). Other non-zero values and ranges are within the scope of the present disclosure.

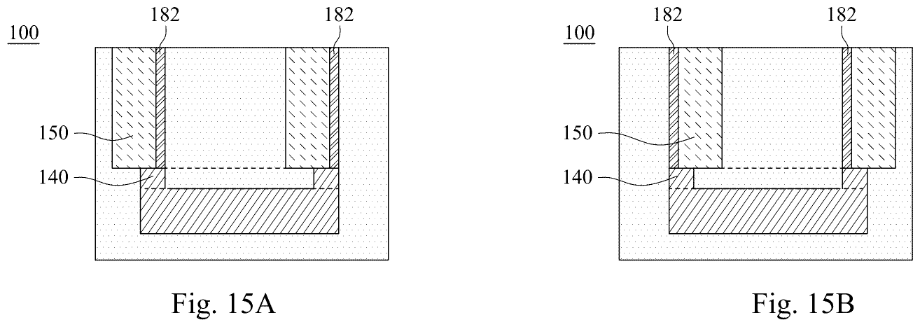

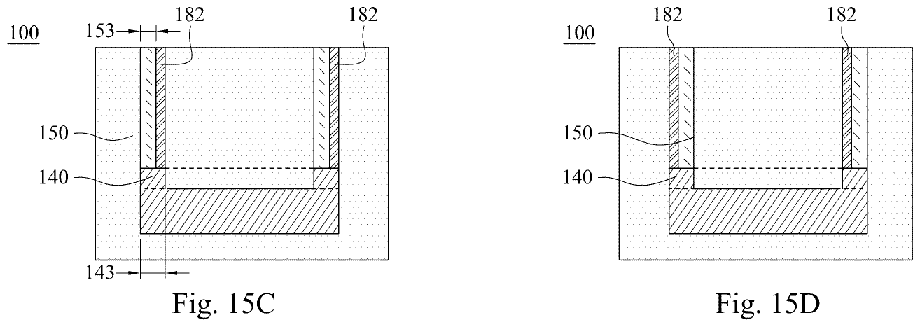

In prior figures, the second dielectric sidewall 150 has been illustrated as being centered over the first dielectric sidewall 140. However, this is not required. FIGS. 15A-15D illustrate different embodiments where the second dielectric sidewall 150 is shifted along the Y-axis relative to the first dielectric sidewall 140. This may occur, for example, due to overlay shift of the photolithographic mask. In FIG. 15A, the second dielectric sidewall 150 is shifted in the negative direction along the Y-axis (i.e. to the left). Portions of the sidewall region 182 are thus illustrated. In FIG. 15B, the second dielectric sidewall 150 is shifted in the positive direction along the Y-axis (i.e. to the right). Portions of the sidewall region 182 are again shown. In FIG. 15C, the thickness 153 of the second dielectric sidewall is less than the thickness 143 of the first dielectric sidewall. Again, the second dielectric sidewall 150 is shifted in the negative direction along the Y-axis. In FIG. 15D, the second dielectric sidewall 150 is shifted in the positive direction along the Y-axis. It is noted in these four figures that the second dielectric sidewall 150 still overlaps the first dielectric sidewall sufficiently to ensure electrical isolation.

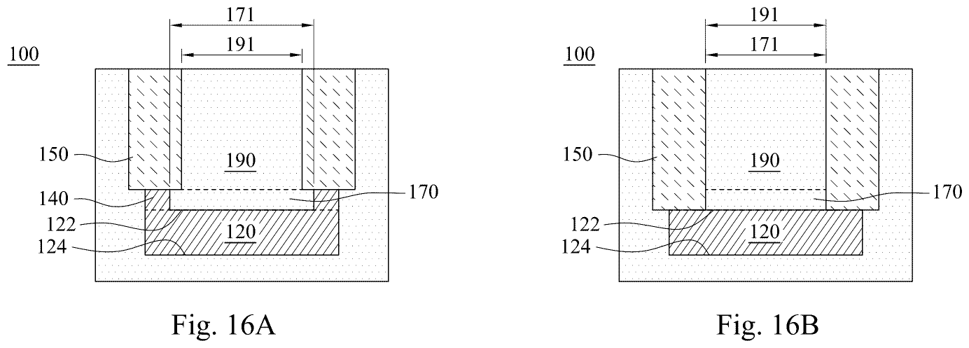

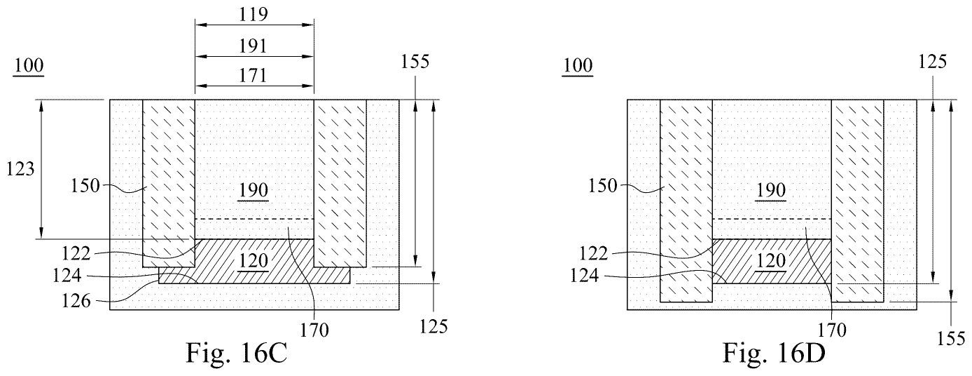

Referring now to FIGS. 16A-16D, the depth/height 155 of the second dielectric sidewall 150 may vary. FIG. 16A illustrates an embodiment where the second dielectric sidewall 150 is located above and contacts the first dielectric sidewall 140. Here, the length 171 of the first substrate region 170 is greater than the length 191 of the second substrate region 190.

In FIG. 16B, however, the first dielectric sidewall is not present. Instead, the second dielectric sidewall 150 contacts the upper surface 122 of the buried dielectric layer 120. The length 171 of the first substrate region 170 is thus about equal to the length 191 of the second substrate region 190. Similarly, in FIG. 16C, the first dielectric sidewall is not present. Instead, the second dielectric sidewall 150 contacts the side surfaces 126 of the buried dielectric layer 120. Put another way, the length 119 of the buried dielectric layer 120 is about equal to the length 171 of the first substrate region 170 and the length 191 of the second substrate region 190. In this embodiment, the depth/height 155 of the second dielectric sidewall 150 is greater than the depth 123 of the upper surface 122 of the buried dielectric layer 120, but is less than the depth 125 of the lower surface 124 of the buried dielectric layer 120. In FIG. 16D, the depth/height 155 of the second dielectric sidewall 150 is greater than the depth 125 of the lower surface 124 of the buried dielectric layer 120. Referring back to step 350 of FIG. 2 and FIGS. 9A-9C, the structure of FIGS. 16B-16D may be formed, for example, by etching the trench 216 deeper, down to the buried dielectric layer 120 and possibly beyond. In some embodiments, then, the etching step 350 of FIG. 2 might be a multi-step process that uses different etchants to remove the sidewall region 182 and the buried dielectric layer 120 (which are made of different materials).

The buried dielectric layer 120 and the dielectric sidewalls 130, 140, 150 may be made of any suitable electrically insulating material, and may be the same or different materials. Suitable examples of electrically insulating materials (i.e. dielectric materials) may include oxides such as silicon dioxide (SiO₂), aluminum oxide (Al₂O₃), tantalum oxide (Ta₂O₅), zirconium dioxide (ZrO₂), or hafnium dioxide (HfO₂); nitrides such as silicon nitride (SiN) or silicon oxynitride (SiON); silicates like hafnium silicate (HfSiO₄) or zirconium silicate (ZrSiO₄); silicon carbide; polysilicon, phosphosilicate glass (PSG), fluorosilicate glass (FSG), undoped silicate glass (USG), high-stress undoped silicate glass (HSUSG), borosilicate glass (BSG), a high-k dielectric material, or a low-k dielectric material.

It is also noted that certain related steps are not expressly described in the discussion above. For example, a pattern/structure may be formed in a given layer by applying a photoresist layer, patterning the photoresist layer, developing the photoresist layer to form a mask, and then etching through the mask to transfer the pattern to the given layer.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the photoresist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern (i.e. a mask). One example of a common developer is aqueous tetramethylammonium hydroxide (TMAH). Generally, any suitable developer may be used. Sometimes, a post develop bake or “hard bake” may be performed to stabilize the photoresist pattern after development, for optimum performance in subsequent steps.

Continuing, portions of the given layer below the patterned photoresist mask are now exposed. Etching transfers the photoresist pattern to the given layer below the patterned photoresist mask. After use, the mask can be removed, for example, using various solvents such as N-methyl-pyrrolidone (NMP) or alkaline media or other strippers at elevated temperatures, or by dry etching using oxygen plasma.

Generally, any etching step described herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

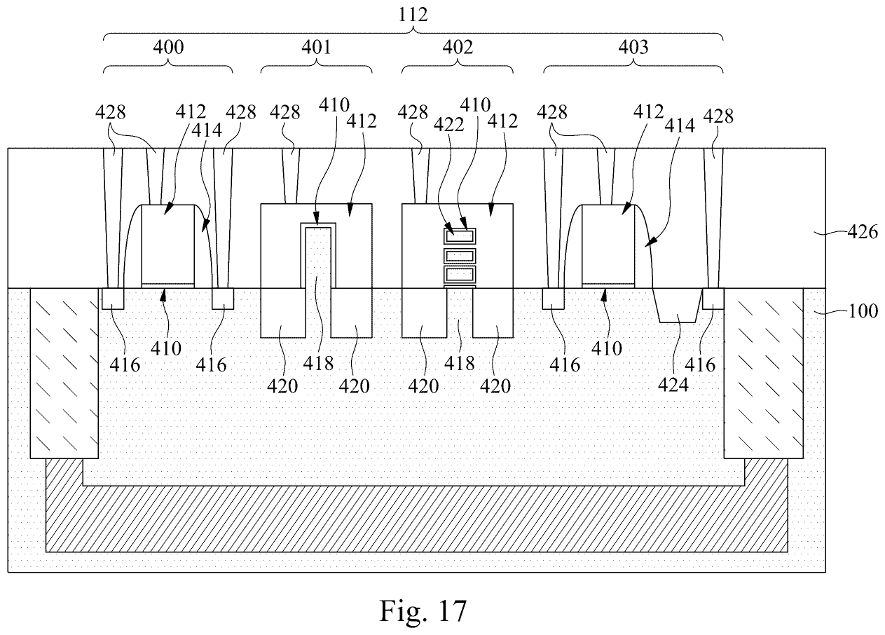

The resulting SOI substrates may subsequently be used in the production of semiconductor devices. FIG. 17 is a Y-axis cross-sectional view illustrating several different kinds of semiconductor devices on an SOI substrate 100.

The first semiconductor device (starting from the left) is a planar transistor 400. As illustrated, a gate dielectric layer 410 is present upon the substrate 100. A gate electrode 412 is located upon the gate dielectric layer 410, and one or more dielectric spacers 414 are present around the gate electrode 412. The gate electrode 412 is located between two source/drain (S/D) electrodes 416.

The second semiconductor device is a FinFET transistor 401. The substrate is shaped to include at least one fin 418. Two shallow trench isolation (STI) regions 420 are shown on either side of the fin. The gate dielectric layer 410 is present upon three sides of the fin 418. A gate electrode 412 is located upon the gate dielectric layer 410, and also surrounds three sides of the fin. The S/D electrodes would be located along the X-axis, and are not visible in this cross-section.

The third semiconductor device is a gate-all-around (GAA) transistor 402. Two STI regions 420 are shown on either side of a semiconducting fin 418. Also located above the fin 418 are plurality of semiconducting channels 422. A gate dielectric layer 410 is present upon the fin and around each semiconducting channel. The gate electrode 412 surrounds the semiconducting channels. The S/D electrodes would be located along the X-axis, and are not visible in this cross-section.

The fourth (furthest to the right) semiconductor device is a lateral diffused metal oxide semiconductor (LDMOS) device 403. This structure is similar to the planar transistor, and includes a gate electrode 412 located upon a gate dielectric layer 410, one or more dielectric spacers 414 around the gate electrode 412, and two source/drain (S/D) electrodes 416. In addition, an STI region 424 is present in the drift region between the gate electrode 412 and one of the S/D electrodes 416.

In each device, vias 428 extend through an interlayer dielectric (ILD) layer 426 to the gate and S/D electrodes 412, 416. Other semiconductor devices or structures may also be formed upon or within the active region 112 of the SOI substrate.

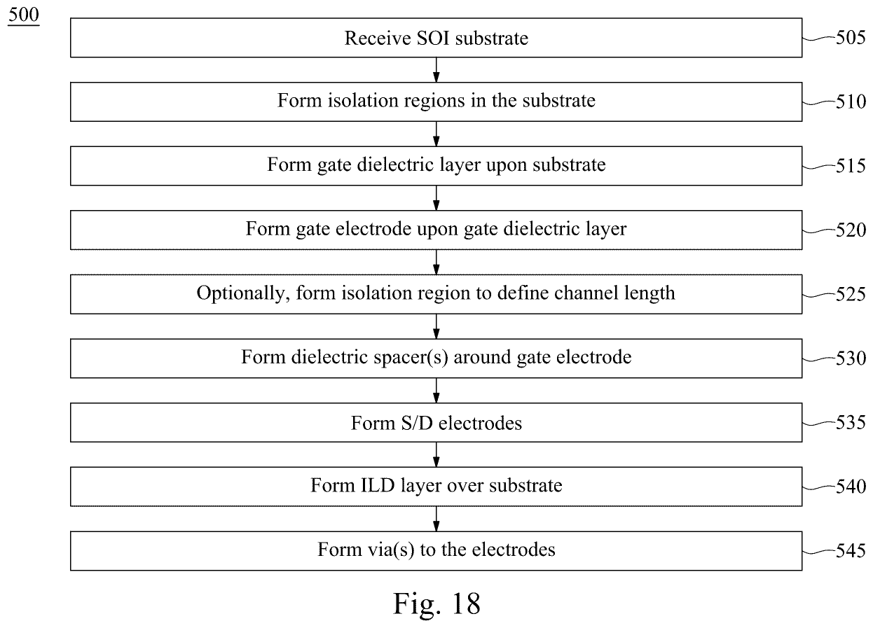

FIG. 18 is a flow chart illustrating a method 500 for forming a semiconductor device on an SOI substrate, in accordance with some embodiments. The method is discussed with reference to FIG. 17. While the method steps are discussed below in terms of forming a single device, such discussion should also be broadly construed as applying to the concurrent formation of multiple devices. The method also describes formation of a planar transistor or an LDMOS transistor, but can be suitably adapted to form other devices. Other structures may also be concurrently formed. It is noted that not all steps described in the flow chart are required.

The method begins in step 505 of FIG. 18, where an SOI substrate 100 is received. Then, in step 510, one or more isolation regions 420 are formed in the active region 112 of the substrate 100. The isolation regions may be, for example, shallow trench isolation (STI) regions or deep trench isolation (DTI) regions. The isolation regions are formed by patterning the substrate, etching isolation trenches, and filling the trenches with a dielectric material. Deposition of dielectric material can be done using CVD, PVD, or spin-on processes known in the art, or the dielectric material can be grown via oxidation. If desired, the dielectric material can be deposited to a level above that of the upper surface 102, then recessed back down to the desired height.

Next, in step 515 of FIG. 18, a gate dielectric layer 410 is formed upon the substrate 100. Again, CVD, PVD, atomic layer deposition (ALD), ion implantation, or other suitable deposition process may be used to form the gate dielectric layer. Thermal oxidation may also be used. The gate dielectric layer 410 is formed between the isolation regions 420. Afterwards, in step 520, a gate electrode 412 is formed upon the gate dielectric layer 410. This may be done by CVD, PVD, or other suitable process. In particular embodiments, the gate precursor layer is made of polysilicon. Next, in step 525 of FIG. 18, an STI region 424 may be formed to one side of the gate electrode. This may aid in reducing hot-carrier injection. In step 530 of FIG. 18, at least one dielectric gate spacer 414 may be formed upon the sidewalls of the gate electrode 412. For example, from a plan view (not shown), one gate spacer may surround the gate electrode on all sides. The gate spacer(s) are vertically oriented, and have a relatively narrow width. The gate spacers can be made from a dielectric material for electrical isolation of the gate electrode. The gate spacer(s) can be made by CVD, PVD, ALD, or other deposition technique. Then, in step 535, source/drain (S/D) electrodes 416 are formed on opposite sides of the gate electrode 412. They may be formed using ion implantation or other suitable methods to dope the silicon substrate, or by patterning and deposition of suitable metals. Next, in step 540 of FIG. 18, an interlayer dielectric (ILD) layer 426 is formed over the substrate. Then, in step 545, vias 428 are formed to the gate electrode 412 and the two S/D electrodes 416.

Such semiconductor devices may be incorporated into larger semiconductor packages and into larger devices. Such packages may also include various interconnect structures for communicating with other semiconductor devices. The semiconductor devices may be useful in power management devices; BCD (Bipolar-CMOS-DMOS) circuits for driving discrete high voltage components; image signal processors (ISP); LCD, OLED, AMOLED, or QLED display panels; image sensors that can be used in systems such as mobile telephones, facial recognition systems, or as motion sensors for automotive applications, security applications, energy efficiency, etc.

The SOI substrates of the present disclosure have several advantages. Full electrical isolation provides better device performance and permits withstanding of higher voltage, which is useful for high-voltage applications. The SOI substrates can be completed using foundry in-house processes. Parasitic capacitance is reduced, and design flexibility is provided by the ability to use different dielectric materials.

Some embodiments of the present disclosure thus relate to methods for forming a silicon-on-insulator (SOI) substrate. A sacrificial layer within a substrate and a first substrate layer over the sacrificial layer are formed. A plurality of vias are formed around a first substrate region of the first substrate layer extending to the sacrificial layer. The sacrificial layer is etched away to form a buried volume. The first substrate region remains connected to the first substrate layer by a plurality of substrate supports. The plurality of substrate supports are then converted into a dielectric material. The buried volume and the plurality of vias are then filled with a first dielectric material to form a buried dielectric layer and a first dielectric sidewall around the first substrate region. A second substrate layer is formed over the first substrate layer. A trench is formed around a second substrate region of the second substrate layer. The trench is filled with a second dielectric material to form a second dielectric sidewall around the second substrate region.

Other embodiments disclosed herein relate to silicon-on-insulator (SOI) substrates. A buried dielectric layer is located within a substrate. A vertical dielectric sidewall extends from the buried dielectric layer to an upper surface of the substrate. The vertical dielectric sidewall surrounds a first substrate region and a second substrate region above the first substrate region. The surface area of the second substrate region is different from the surface area of the first substrate region (when considered from a plan view).

Also described in various embodiments herein are methods for forming a semiconductor device. A silicon-on-insulator (SOI) substrate is received, which has the structure described above. Source/drain electrodes are formed in the second substrate region. A gate dielectric layer is formed upon the second substrate region. A gate electrode is formed upon the gate dielectric layer. Also disclosed are such semiconductor devices on an SOI substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a sacrificial layer within a substrate and a first substrate layer over the sacrificial layer;
forming a plurality of vias around a first substrate region of the first substrate layer extending to the sacrificial layer;
etching away the sacrificial layer to form a buried volume, wherein the first substrate region is connected to the first substrate layer by a plurality of substrate supports;
converting the plurality of substrate supports into a dielectric material;
filling the buried volume and the plurality of vias with a first dielectric material to form a buried dielectric layer and a first dielectric sidewall around the first substrate region;
forming a second substrate layer over the first substrate layer;
forming a trench around a second substrate region of the second substrate layer; and
filling the trench with a second dielectric material to form a second dielectric sidewall around the second substrate region.

2. The method of claim 1, wherein the sacrificial layer and the first substrate layer are formed by:
forming the sacrificial layer within an upper surface of the substrate; and
depositing the first substrate layer over the upper surface of the substrate.

3. The method of claim 1, wherein the sacrificial layer and the first substrate layer are formed by:
implanting ions within the substrate to form the sacrificial layer;
wherein the first substrate layer is a layer of the substrate located above the sacrificial layer.

4. The method of claim 1, further comprising planarizing the second substrate layer after the second dielectric sidewall is formed.

5. The method of claim 1, wherein the first dielectric material is deposited by chemical vapor deposition (CVD).

6. The method of claim 1, wherein the sacrificial layer is etched away using a selective gas etchant.

7. The method of claim 1, wherein the plurality of substrate supports are converted into a dielectric material by oxidation.

8. The method of claim 1, wherein the first dielectric material and the second dielectric material are silicon dioxide.

9. The method of claim 1, wherein a depth of the second substrate region is greater than a depth of the first substrate region.

10. The method of claim 1, wherein a surface area of the second substrate region is less than a surface area of the first substrate region.

11. The method of claim 1, wherein a thickness of the second dielectric sidewall is greater than a thickness of the first dielectric sidewall.

12. The method of claim 1, wherein the second substrate region is not centered along its width and length over the first substrate region.

13. The method of claim 1, wherein the trench formed around the second substrate region extends down to the first dielectric sidewall.

14. The method of claim 1, wherein the formation of the trench around the second substrate region removes the first dielectric sidewall.

15. A structure, comprising:
a buried dielectric layer within a substrate; and
a dielectric sidewall extending from the buried dielectric layer to an upper surface of the substrate,
wherein the dielectric sidewall surrounds a first substrate region and a second substrate region above the first substrate region;
wherein an area of the second substrate region is different from an area of the first substrate region.

16. The SOI substrate of claim 15, wherein the area of the second substrate region is less than the area of the first substrate region.

17. The SOI substrate of claim 15, wherein the second substrate region is not centered along its width and length over the first substrate region.

18. The SOI substrate of claim 15, wherein the dielectric sidewall comprises a first dielectric sidewall below a second dielectric sidewall;
wherein a thickness of the first dielectric sidewall is different from a thickness of the second dielectric sidewall.

19. A method, comprising:
receiving a silicon-on-insulator (SOI) substrate comprising:
a buried dielectric layer within a substrate; and
a vertical dielectric sidewall extending from the buried dielectric layer to an upper surface of the substrate,
wherein the vertical dielectric sidewall surrounds a first substrate region and a second substrate region above the first substrate region;
wherein a surface area of the second substrate region is different from a surface area of the first substrate region; and
forming source/drain electrodes in the second substrate region;
forming a gate dielectric layer upon the second substrate region; and
forming a gate electrode upon the gate dielectric layer.

20. The method of claim 19, further comprising forming isolation regions in the second substrate region.
